(19) United States
(12) Patent Application Publication
(10) Pub. No.: US 2015/0144317 A1
(43) Pub. Date: May 28, 2015

(54) HEAT DISSIPATING MODULE

(71) Applicant: HON HAI PRECISION INDUSTRY CO., LTD., New Taipei (TW)

(72) Inventor: MENG-HSIEN LIN, New Taipei (TW)

(21) Appl. No.: 14/477,173

(22) Filed: Sep. 4, 2014

(30) Foreign Application Priority Data
Nov. 26, 2013 (TW) 102143082

(51) Int. Cl. H05K 7/20; F28F 3/00

(52) U.S. Cl. CPC H05K 7/20409; F28F 3/00
USPC 165/185

(57) ABSTRACT

A heat dissipating module includes a heat sink and a number of latching assemblies. The heat sink includes a base and a number of positioning portions. A number of positioning holes is defined extending through the corresponding positioning portions and the base. Each latching assembly includes a latching member and a resilient member.

The latching member includes a connecting pole, a head located at a first end portion of the connecting pole, and a latching portion located at a second end portion of the connecting pole. The resilient member is sleeved around the connecting pole. The latching portions of the latching members are extended through the corresponding positioning holes and engaged with a bottom surface of the base. Each resilient member is pressed between the corresponding head and the corresponding positioning portion.

### FIELD

The present disclosure relates to a heat dissipating module.

### BACKGROUND

A heat sink is usually placed in thermal contact with an electronic package, such as a south bridge or north bridge chipset, and transfers heat through conduction away from the electronic package so as to prevent over-heating of the electronic package. Usually, a plurality of securing members is mounted on a circuit board, and a heat sink is secured to an electronic package by using a clip engaged with the corresponding securing members.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an exploded, isometric view of an embodiment of a heat dissipating module.

FIG. 2 is an assembled view of FIG. 1.

FIG. 3 is a sectional view of FIG. 2, taken along line III-III.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean “at least one.”

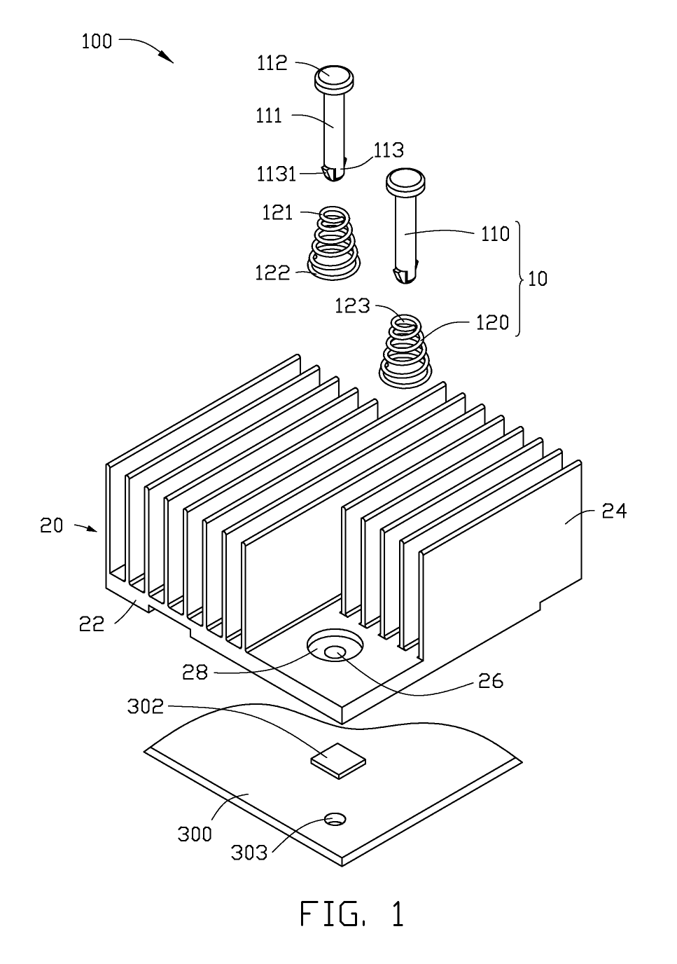

FIG. 1 illustrates an embodiment of a heat dissipating module 100 comprising a heat sink 20 and two latching assemblies 10. The latching assemblies 10 are used for mounting the heat sink 20 to a circuit board 300. An electronic package 302 is mounted on the circuit board 300, and the circuit board 300 defines a plurality of latching holes 303 surrounding the electronic package 302. In the embodiment, the electronic package 302 is a south bridge.

The heat sink 20 comprises a substantially rectangular base 22, and a plurality of fins 24 substantially perpendicularly extending from the base 22. Each of two opposite corner portions of the base 22 defines a substantially circular positioning hole 26. The base 22 further comprises two positioning portions 28. Each positioning portion 28 surrounds one corresponding positioning hole 26. In the embodiment, each positioning portion 28 is a substantially annular positioning slot. The positioning slot is defined in a top surface of the base 22, and each positioning slot communicates with the corresponding positioning hole 26. In another embodiment, each positioning portion 28 can be a substantially annular protrusion extending from the base 22 and surrounding the corresponding positioning hole 26.

Each latching assembly 10 comprises a latching member 110 and a resilient member 120.

Each latching member 110 comprises a substantially cylindrical connecting pole 111, a substantially circular head 112 located at a top end portion of the connecting pole 111, and a latching portion 113 located at a bottom end portion of the connecting pole 111. A diameter of the head 112 is greater than a diameter of the connecting pole 111. The latching portion 113 comprises two opposite and resilient latching blocks 1131 protruding from a circumference of the latching portion 113.

Each resilient member 120 is tapered and comprises a top end portion 121 and a bottom end portion 122. An outer diameter of the bottom end portion 122 is greater than an outer diameter of the top end portion 121. A through hole 123 is defined along an axial direction of the resilient member 120. In the embodiment, the resilient member 120 is a tapered spring. In another embodiment, the resilient member 120 can be a tapered pliable plastic block.

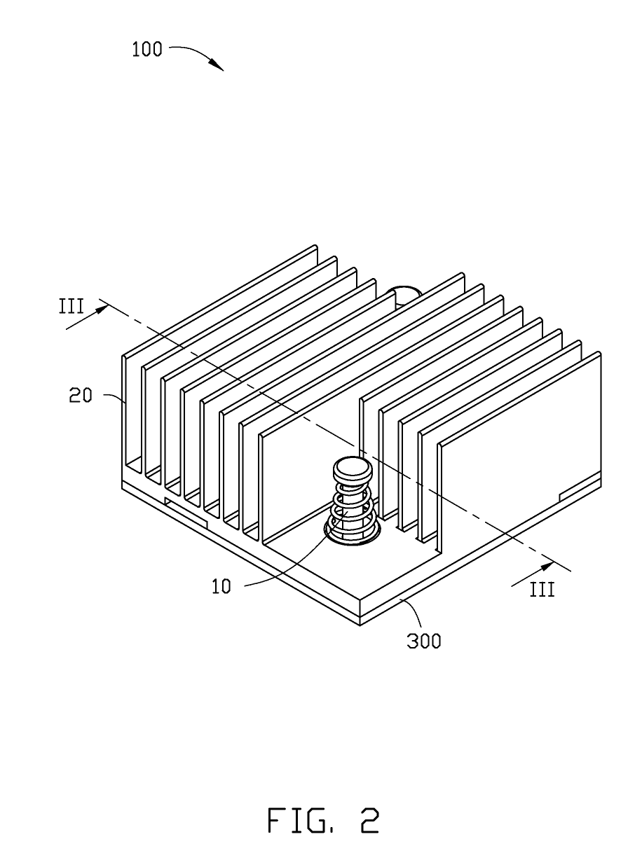

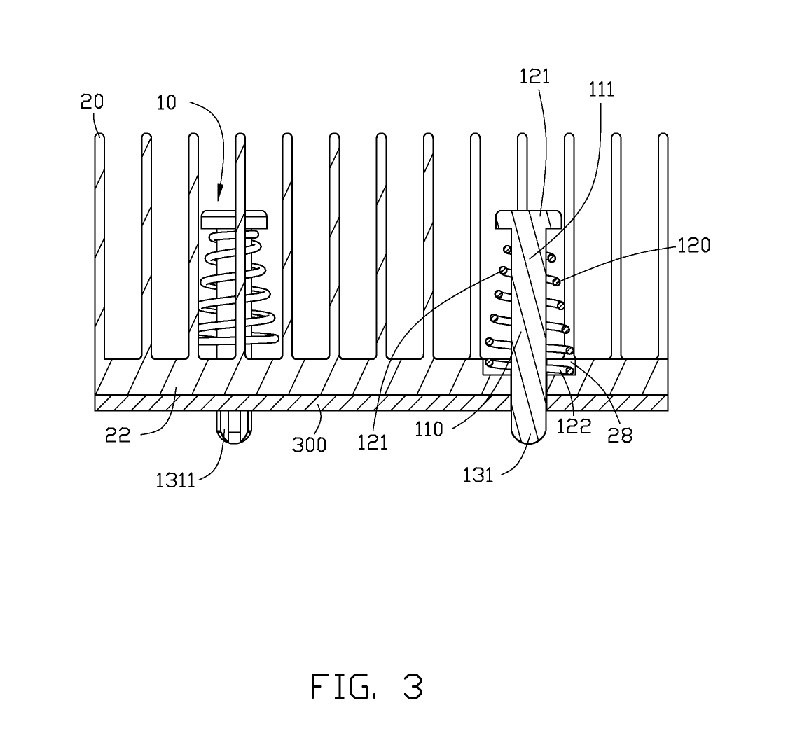

FIGS. 2 and 3 illustrate assembled views of the heat dissipating module 100. The bottom end portions 122 of the resilient members 120 are received in the corresponding positioning portions 28. Thus, the resilient members 120 are positioned in the corresponding positioning portions 28, and the through hole 123 of each resilient member 120 is aligned with the corresponding positioning hole 26. The latching portion 113 of each latching member 110 is inserted into the through hole 123 of the corresponding resilient member 120, and the corresponding positioning hole 26. The latching blocks 1131 of each latching member 110 slidably resist against an inner wall bounding the corresponding positioning hole 26, to deform the latching blocks 1131, until the latching blocks 1131 extend through a bottom surface of the base 22. The latching blocks 1131 of each latching member 110 are restored to latch to a bottom surface of the base 22, thus preventing the latching member 110 from disengaging from the corresponding positioning hole 26. Thus, the resilient members 120 are sleeved around the connecting poles 111, the latching members 110 are assembled in the positioning holes 26 of the heat sink 20, the top end portion 121 of each resilient member 120 resiliently abuts against the corresponding head 112, and the bottom end portion 122 is received in the corresponding positioning portion 28.

When the heat dissipating module 100 is assembled to the circuit board 300, the bottom surface of the base 22 is engaged with a top surface of the electronic package 302, and the latching portions 113 are aligned with the latching holes 303. The latching members 110 are pressed toward the circuit board 300, causing the latching portions 113 to be inserted into the corresponding latching holes 303. The latching blocks 1131 of each latching member 110 slidably resists against an inner wall bounding the corresponding latching hole 303, to deform the latching blocks 1131 and the corresponding resilient member 120, until the latching blocks 1131 extend through a bottom surface of the circuit board 300. The latching blocks 1131 of each latching member 110 are restored to latch to the bottom surface of the circuit board 300. Thus, the heat dissipating module 100 is mounted to the circuit board 300.

Each resilient member 120 is resiliently pressed between the head 112 of the corresponding latching member 110, and the corresponding positioning portion 28, thus preventing the corresponding connecting pole 111 from moving along the base 22.

Even though numerous characteristics and advantages of the embodiments have been set forth in the foregoing description, together with details of the structure and function of the embodiments, the present disclosure is illustrative only, and changes may be made in detail, especially in the matters of shape, size, and arrangement of parts within the principles of the embodiments to the full extent indicated by the broad general meaning of the terms in which the appended claims are expressed.

What is claimed is:

1. A heat dissipating module, comprising:
a heat sink comprising a base and a plurality of positioning portions located on the base, wherein a top surface of the base defines a plurality of positioning holes extending through the corresponding positioning portions and the base; and
a plurality of latching assemblies, wherein each latching assembly comprises a latching member and a resilient member, the latching member comprises a connecting pole, a head located at a first end of the connecting pole, and a latching portion located at a second end of the connecting pole opposite to the head, the resilient member is fitted about the connecting pole, the latching portions of the latching members are extended through the positioning holes and positioned to a bottom surface of the base, each resilient member is sandwiched between the corresponding head and the corresponding positioning portion, and each resilient member is positioned to the corresponding positioning portion.

2. The heat dissipating module of claim 1, wherein each resilient member comprises a top end portion resisting against the corresponding head and a bottom end portion resisting against the corresponding positioning portion, the resilient member defines a through hole extending through the top and bottom end portions of the resilient member, and each connecting pole is received in the corresponding through hole.

3. The heat dissipating module of claim 2, wherein each positioning portion is an annular positioning slot surrounding the corresponding positioning hole, and the bottom end portion of each resilient member is positioned in the corresponding positioning slot.

4. The heat dissipating module of claim 1, wherein each resilient member is a tapered spring.

5. The heat dissipating module of claim 1, wherein the latching portion comprises two resilient latching blocks, the latching blocks of the latching member extend through the corresponding positioning hole, and the latching blocks slidably abut against an inner wall bounding the positioning holes, to deform the latching blocks, until the latching blocks latch to the bottom surface of the base.
